(19) United States
(12) Patent Application Publication
(10) Pub. No.: US 2015/0041197 A1
(43) Pub. Date: Feb. 12, 2015

(54) EMBEDDED MULTILAYER CERAMIC ELECTRONIC COMPONENT AND PRINTED CIRCUIT BOARD HAVING THE SAME

(71) Applicant: SAMSUNG ELECTRO-MECHANICS CO., LTD., Suwon (KR)

(72) Inventors: Byoung Hwa Lee, Suwon (KR); Hai Joon Lee, Suwon (KR); Tae Hyeok Kim, Suwon (KR); Jin Man Jung, Suwon (KR); Eun Hyuk Chae, Suwon (KR)

(73) Assignee: SAMSUNG ELECTRO-MECHANICS CO., LTD., Suwon (KR)

(21) Appl. No.: 14/147,204

(22) Filed: Jan. 3, 2014

(30) Foreign Application Priority Data
Aug. 8, 2013 (KR) 10/2013-0093947

(51) Int. Cl. H01G 4/30; H05K 1/18; H01G 4/005

(52) U.S. Cl. CPC H01G 4/30; H01G 4/005; H05K 1/185; H05K 2201/10439
USPC 174/260; 361/301.4

(57) ABSTRACT

There is provided an embedded multilayer ceramic electronic component including: a ceramic body including dielectric layers; first internal electrodes and second internal electrodes having first and second leads; first dummy electrodes and second dummy electrodes; and first and second external electrodes, wherein when a length from ends of the first and second external electrodes formed on first and second lateral surfaces of the ceramic body to the first and second external electrodes corresponding to the first and second leads is G, a length of the first and second external electrodes formed on the first and second lateral surfaces of the ceramic body up to end surfaces of the ceramic body is BW, and a length from the end surfaces of the ceramic body to the first and second external electrodes corresponding to the first and second leads is M, 30 μm≦G<BW−M is satisfied.

### CROSS-REFERENCE TO RELATED APPLICATION

This application claims the benefit of Korean Patent Application No. 10-2013-0093947 filed on Aug. 8, 2013, with the Korean Intellectual Property Office, the disclosure of which is incorporated herein by reference.

### BACKGROUND

The present disclosure relates to an embedded multilayer ceramic electronic component and a printed circuit board having the same.

As electronic circuits have been highly densified and highly integrated, a mounting space for passive elements mounted on printed circuit boards (PCB) has been insufficient, and in order to solve this problem, ongoing efforts have been attempted to implement components able to be installed within boards, i.e., embedded devices. In particular, various methods have been proposed for installing multilayer ceramic electronic components used as capacitive components within boards.

Among a variety of methods of installing multilayer ceramic electronic components within boards, a method in which materials of boards were used as dielectric materials for multilayer ceramic electronic components and copper wirings and the like were used as electrodes has been used. Other methods for implementing embedded multilayer ceramic electronic components include a method of forming embedded multilayer ceramic electronic components by forming polymer sheets having high-k dielectrics or dielectric thin films within boards, a method of installing multilayer ceramic electronic components within boards, and the like.

In general, multilayer ceramic electronic components include a plurality of dielectric layers formed of a ceramic material, and internal electrodes interposed between the dielectric layers. By disposing multilayer ceramic electronic components within boards, embedded multilayer ceramic electronic components having high capacitance may be implemented.

In order to manufacture printed circuit boards (PCB) including embedded multilayer ceramic electronic components, multilayer ceramic electronic components may be inserted into core boards, and via holes are required to be formed in upper multilayer plates and lower multilayer plates by using a laser beam in order to connect board wirings and external electrodes of the multilayer ceramic electronic components. Laser beam machining, however, considerably increases manufacturing costs of PCBs.

Meanwhile, embedded multilayer ceramic electronic components are installed in core parts within boards, so nickel/tin (Ni/Sn) plated layers are not required to be formed on external electrodes thereof, unlike general multilayer ceramic electronic components mounted on board surfaces.

Namely, external electrodes of embedded multilayer ceramic electronic components are electrically connected to circuits within boards through vias of which a material is copper (Cu), and thus, copper (Cu) layers, instead of nickel/tin (Ni/Sn) layers, are required to be formed on the external electrodes.

In general, external electrodes may use copper (Cu) as a main ingredient, but since external electrodes include glass, a component included in glass may absorb a laser beam in the event of laser beam machining to form vias within boards, such that process depths of vias may not be able to be adjusted.

For this reason, copper (Cu) plated layers are separately formed on external electrodes of embedded multilayer ceramic electronic components.

Also, when vias are processed to connect external electrodes of the embedded multilayer ceramic electronic components and circuits within boards therethrough, dimple deficiency, a problem in which vias are lopsided due to an uneven configuration of external electrodes may occur frequently, degrading reliability.

Meanwhile, embedded multilayer ceramic electronic components are embedded in printed circuit boards (PCB) used in memory cards, PC main boards, and various RF modules and thus may allow for the size of products to be remarkably reduced as compared to mounted multilayer ceramic electronic components.

Also, since embedded multilayer ceramic electronic components may be disposed within a significantly short range from input terminals of active elements such as micro-processor units (MPU), interconnect inductance due to lengths of electric lines may be reduced.

However, such an effect of reducing inductance in the embedded multilayer ceramic electronic components is merely an effect resulting from a reduction in interconnect inductance obtained by an inherent disposition relationship of the embedding scheme, and the demand for improvement of equivalent series inductance (ESL) characteristics of embedded multilayer ceramic electronic components themselves remains required.

In general, in embedded multilayer ceramic electronic components, in order to lower ESL, current paths within the multilayer ceramic electronic components are required to be reduced.

However, since copper (Cu) plated layers are formed on external electrodes of embedded multilayer ceramic electronic components, a plating solution may infiltrate into the external electrodes, such that it may be difficult to shorten internal current paths.

### RELATED ART DOCUMENT

Korean Patent Laid-Open Publication No. 10-2006-0073274

### SUMMARY

An aspect of the present disclosure may provide an embedded multilayer ceramic electronic component and a printed circuit board (PCB) having the same.

According to an aspect of the present disclosure, an embedded multilayer ceramic electronic component may include: a ceramic body including dielectric layers and having first and second main surfaces opposing each other, first and second side surfaces opposing each other, and first and second end surfaces opposing each other; first internal electrodes and second internal electrodes stacked on each other, having the dielectric layer interposed therebetween, and having first and second leads exposed to the first and second side surfaces, respectively; first dummy electrodes formed to be coplanar with the first internal electrodes and spaced apart from each other by a predetermined distance; and second dummy electrodes formed to be coplanar with the second internal electrodes and spaced apart from each other by a predetermined distance; and first and second external electrodes formed to extend from the first and second end surfaces of the ceramic body to the first and second main surfaces and the first and second side surfaces thereof, respectively, wherein when a distance from ends of the first and second external electrodes formed on the first and second side surfaces of the ceramic body to a portion of the first and second external electrodes corresponding to an edge of the first and second leads is G, a distance of the first and second external electrodes formed on the first and second side surfaces of the ceramic body to the end surfaces of the ceramic body is BW, and a distance from the end surfaces of the ceramic body to a portion of the first and second external electrodes corresponding to an edge of the first and second leads is M, 30 μm≦G<BW−M is satisfied.

The distance M from the end surfaces of the ceramic body to the portion of the first and second external electrodes corresponding to the edge of the first and second leads may satisfy 50 μm≦M<BW−G.

Distances of the first and second dummy electrodes in the length direction of the ceramic body may be equal to or less than 30 μm.

The first and second leads may be spaced apart from both end surfaces of the ceramic body by a predetermined distance.

An average thickness of the first and second external electrodes formed on the first and second side surfaces of the ceramic body may be equal to or more than 5 μm.

The first and second external electrodes may include a metal layer formed of copper (Cu) formed thereon.

The metal layer may be formed through plating.

According to another aspect of the present disclosure, an embedded multilayer ceramic electronic component may include a ceramic body including dielectric layers and having first and second main surfaces opposing each other, first and second side surfaces opposing each other, and first and second end surfaces opposing each other; first internal electrodes and second internal electrodes stacked on each other, having the dielectric layer interposed therebetween, and having first and second leads exposed to the first and second side surfaces of the ceramic body, respectively; first dummy electrodes formed to be coplanar with the first internal electrodes and spaced apart from each other by a predetermined distance, and second dummy electrodes formed to be coplanar with the second internal electrodes and spaced apart from each other by a predetermined distance; and first and second external electrodes formed to extend from the first and second end surfaces of the ceramic body to the first and second main surfaces and the first and second side surfaces thereof, respectively, wherein when a distance from ends of the first and second external electrodes formed on the first and second side surfaces of the ceramic body to a portion of the first and second external electrodes corresponding to an edge of the first and second leads is G, a distance of the first and second external electrodes formed on the first and second side surfaces of the ceramic body to the end surfaces of the ceramic body is BW, and a distance from the end surfaces of the ceramic body to a portion of the first and second external electrodes corresponding to an edge of the first and second leads is M, 50 μm≦M<BW−G is satisfied.

Distances of the first and second dummy electrodes in the length direction of the ceramic body may be equal to or less than 30 μm.

The first and second leads may be spaced apart from both end surfaces of the ceramic body by a predetermined distance.

An average thickness of the first and second external electrodes formed on the first and second side surfaces of the ceramic body may be equal to or more than 5 μm.

The first and second external electrodes may include a metal layer formed of copper (Cu) formed thereon.

The metal layer may be formed through plating.

According to another aspect of the present disclosure, a printed circuit board (PCB) having an embedded multilayer ceramic electronic component may include: an insulating substrate; and the embedded multilayer ceramic electronic component as described above, installed in the insulating substrate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view of an embedded multilayer ceramic electronic component according to an exemplary embodiment of the present disclosure;

FIG. 2 is a cross-sectional view taken along line X-X′ of FIG. 1;

FIG. 3 is a cross-sectional view taken along line Y-Y′ of FIG. 1;

FIG. 4 is a cross-sectional view taken along line Y-Y′ of FIG. 1 according to another exemplary embodiment of the present disclosure;

FIG. 5 is a cross-sectional view taken along line Y-Y′ of FIG. 1 according to another exemplary embodiment of the present disclosure; and

FIG. 6 is a cross-sectional view of a printed circuit board (PCB) including an embedded multilayer ceramic electronic component therein according to an exemplary embodiment of the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

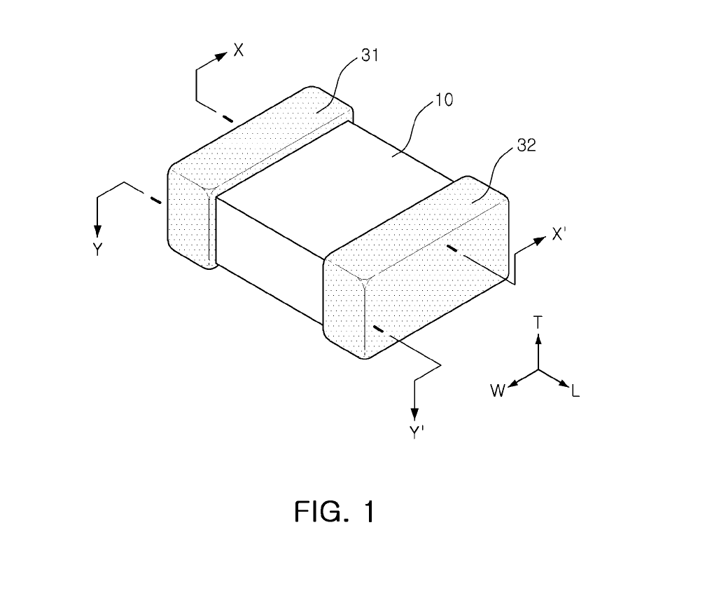

FIG. 1 is a perspective view of an embedded multilayer ceramic electronic component according to an exemplary embodiment of the present disclosure.

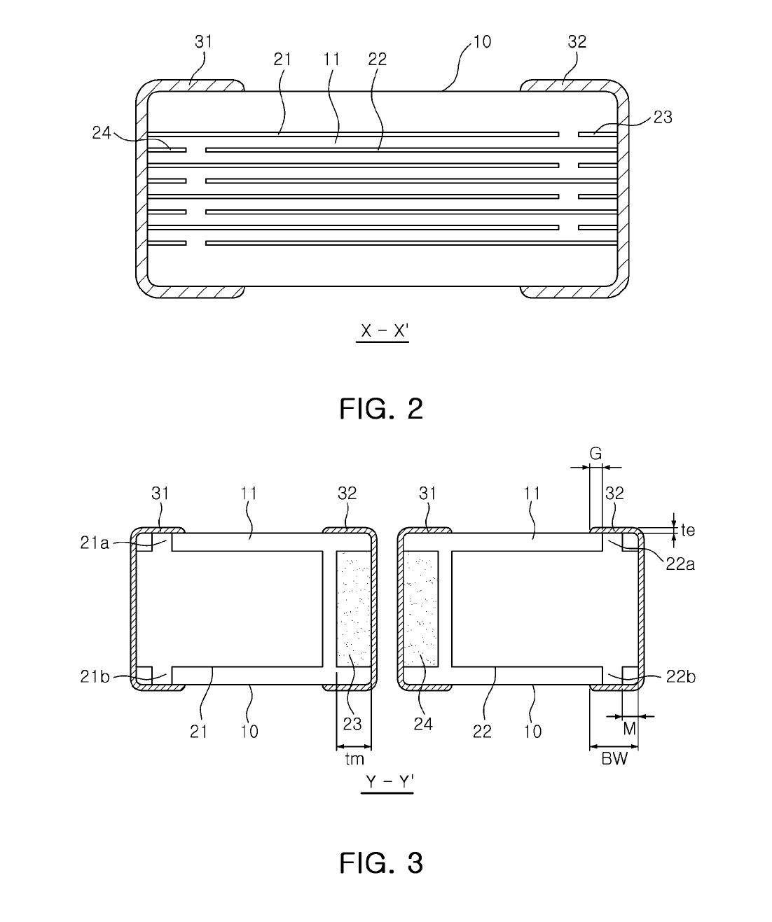

FIG. 2 is a cross-sectional view taken along line X-X′ of FIG. 1.

FIG. 3 is a cross-sectional view taken along line Y-Y′ of FIG. 1.

Referring to FIGS. 1 and 2, an embedded multilayer ceramic electronic component according to an exemplary embodiment of the present disclosure may include a ceramic body 10 including dielectric layers 11 and having first and second main surfaces opposing each other, first and second side surfaces opposing each other, and first and second end surfaces opposing each other; first internal electrodes 21 and second internal electrodes 22 stacked on each other, having the dielectric layers 11 interposed therebetween and having first and second leads 21a, 21b, 22a, and 22b exposed to the first and second side surfaces of the ceramic body, respectively; first dummy electrodes 23 formed to be coplanar with the first internal electrodes 21 and spaced apart from each other by a predetermined distance; and second dummy electrodes 24 formed to be coplanar with the second internal electrodes 22 and spaced apart from each other by a predetermined distance; and first and second external electrodes 31 and 32 formed to extend from the first and second end surfaces of the ceramic body 10 to the first and second main surfaces and the first and second side surfaces thereof, respectively.

Hereinafter, a multilayer ceramic electronic component according to an exemplary embodiment of the present disclosure will be described. In particular, a multilayer ceramic capacitor (MLCC) will be described as an example, but the present inventive concept is not limited thereto.

In the multilayer ceramic capacitor (MLCC) according to an exemplary embodiment of the present disclosure, it is defined that a ‘length direction’ is the ‘L’ direction, a ‘width direction’ is the ‘W’ direction, and a ‘thickness direction’ is the ‘T’ direction in FIG. 1. Here, the ‘thickness direction’ may be a ‘stacking direction’ in which dielectric layers are stacked.

In an exemplary embodiment of the present disclosure, the ceramic body 10 may have a hexahedral shape as illustrated in FIG. 1, but a shape of the ceramic body 10 is not particularly limited.

In an exemplary embodiment of the present disclosure, the ceramic body 10 may have the first and second main surfaces opposing each other and the first and second side surfaces opposing each other, and the first and second end surfaces opposing each other, and the first and second main surfaces may also be expressed as upper and lower surfaces of the ceramic body 10.

A material used to form the dielectric layers 11 is not particularly limited as long as it may obtain sufficient capacitance. For example, barium titanate (BaTiO₃) powder may be used.

As for the material of the dielectric layers 11, various ceramic additives, organic solvents, plasticizers, binders, dispersing agents, and the like, may be added to the barium titanate (BaTiO₃) powder, or the like, as needed, according to an embodiment of the present disclosure.

An average particle diameter of the ceramic powder used to form the dielectric layers 11 is not particularly limited and may be adjusted, as needed, according to an embodiment of the present disclosure. For example, the average particle diameter of the ceramic powder may be adjusted to be equal to or less than 400 nm.

A material used to form the first and second internal electrodes 21 and 22 is not particularly limited. For example, the first and second internal electrodes 21 and 22 may be formed of a conductive paste including one or more materials among precious metals such as palladium (Pd), a palladium-silver (Pd—Ag) alloy, and the like, and nickel, and copper.

The first internal electrode 21 and the second internal electrode 22 are stacked on each other, having the dielectric layer 11 interposed therebetween, and the first internal electrode 21 has first and second leads 21a and 21b exposed to the first and second side surfaces of the ceramic body 10.

Also, the second internal electrode 22 has first and second leads 22a and 22b exposed to the first and second side surfaces of the ceramic body 10.

The first and second leads 22a and 22b of the second internal electrode 22 may be exposed to the first and second side surfaces such that the first and second leads 22a and 22b are spaced apart from the first and second leads 21a and 21b of the first internal electrode 21 by a predetermined distance.

Also, the first internal electrode 21 and the second internal electrode 22 may be electrically connected to the first and second external electrodes 31 and 32 to be described below through the first and second leads 21a, 21b, 22a, and 22b exposed to the first and second side surfaces of the ceramic body 10.

Namely, the first and second leads 21a and 21b of the first internal electrode 21 are connected to the first external electrode 31 and the first and second lead 22a and 22b of the second internal electrode 22 may be connected to the second external electrode 32.

Accordingly, in comparison to a general configuration in which internal electrodes are connected to external electrodes through both end surfaces of a ceramic body, since the internal electrodes are extended to the side surfaces of the ceramic body so as to be exposed thereto, a current path may be relatively shortened to reduce equivalent series resistor (ESR).

The first and second leads 21a, 21b, 22a, and 22b may be formed to be spaced apart from both end surfaces of the ceramic body 10 by a predetermined distance.

Here, since the first and second leads 21a, 21b, 22a, and 22b are formed to be spaced apart from both end surfaces of the ceramic body 10 and are not extended to corner portions of the ceramic body 10, degradation of reliability due to infiltration of a plating solution may be prevented.

Also, since a current flows through the first and second leads 21a, 21b, 22a, and 22b, a current path may be relatively shortened to reduce ESL.

Also, since the first and second leads 21a and 21b of the first internal electrode 21 and the first and second leads 22a and 22b of the second internal electrode 22 are exposed to the first and second side surfaces, flatness of the external electrodes of the MLCC in the width direction may be improved.

In general, a width directional marginal portion in which an internal electrode is not present is provided in the width direction of the ceramic body, and the presence of the width directional marginal portion generates a step to cause external electrodes of a completed chip to be bent while degrading flatness.

In the case in which flatness of the MLCC in the width direction is degraded, dimple deficiency, a problem in which vias are lopsided at the time of performing a via process for an electrical connection thereof with a board may occur.

However, according to an exemplary embodiment of the present disclosure, since the first and second leads 21a and 21b of the first internal electrode 21 and the first and second leads 22a and 22b of the second internal electrode 22 are exposed to the first and second side surfaces, reducing the occurrence of a step in the ceramic body 10 in the width direction, the flatness of the external electrodes of a completed chip may be enhanced and, as a result, dimple deficiency, a problem in which vias are lopsided may be reduced.

Meanwhile, the embedded MLCC according to an exemplary embodiment of the present disclosure may include the first dummy electrode 23 formed to be coplanar with the first internal electrode 21 and spaced apart from the first internal electrode by a predetermined distance and the second dummy electrode 24 formed to be coplanar with the second internal electrode 22 and spaced apart from the second internal electrode 22 by a predetermined distance.

Since the first dummy electrode 23 are formed to be coplanar with the first internal electrode 21 and spaced apart from the first internal electrode by a predetermined distance and the second dummy electrode 24 are formed to be coplanar with the second internal electrode 22 and spaced apart from the second internal electrode 22 by a predetermined distance, the flatness of the external electrode of the MLCC in the length direction may be enhanced.

In general, a length directional marginal portion in which an internal electrode is not present is provided in the length direction of the ceramic body, and the presence of the length directional marginal portion causes the occurrence of a step to cause external electrodes of a completed chip to be bent while degrading flatness.

In the case in which flatness of the MLCC in the length direction is degraded, dimple deficiency, a problem in which vias are lopsided when a via process for an electrical connection with a board is performed may occur.

However, according to an exemplary embodiment of the present disclosure, since the first dummy electrode 23 are formed to be coplanar with the first internal electrode 21 and spaced apart from the first internal electrode by a predetermined distance and the second dummy electrode 24 are formed to be coplanar with the second internal electrode 22 and spaced apart from the second internal electrode 22 by a predetermined distance within the ceramic body 10, the occurrence of a step of the ceramic body 10 in the length direction may be reduced to enhance flatness of the external electrodes of a completed chip and, as a result, dimple deficiency, a problem in which the vias are lopsided may be reduced.

Distances of the first and second dummy electrodes 23 and 24 in the length direction of the ceramic body 10 may be equal to or less than 30 lam, but the present inventive concept is not necessarily limited thereto.

By forming the first and second dummy electrodes 23 and 24 to have the distances equal to or less than 30 μm in the length direction of the ceramic body 10, flatness of the external electrodes of the MLCC in the length direction may be enhanced, reducing dimple deficiency, a problem in which vias are lopsided when a via process for an electrical connection with a board is performed.

When the length of the first and second dummy electrodes 23 and 24 in the length direction of the ceramic body 10 exceeds 30 μm, since a distance between the first and second dummy electrodes 23 and 24 and the first and second internal electrodes 21 and 22 is relatively short, short deficiency may occur due to printing spread.

Meanwhile, a lower limit value of the distances of the first and second dummy electrodes 23 and 24 in the length direction of the ceramic body 10 is not particularly limited and, for example, may be equal to or more than 1 μm.

According to an exemplary embodiment of the present disclosure, the first and second external electrodes 31 and 32 may be formed to extend from the first and second end surfaces of the ceramic body 10 to the first and second main surfaces and the first and second side surfaces.

The first and second external electrodes 31 and 32 may be formed to include a conductive metal and glass.

In order to form capacitance, the first and second external electrodes 31 and 32 may be formed to extend from the first and second end surfaces of the ceramic body 10 to the first and second main surfaces and the first and second side surfaces, and may be electrically connected to the first and second internal electrodes 21 and 22 through the first and second leads 21a, 21b, 22a, and 22b, exposed to the first and second side surfaces of the ceramic body 10, respectively.

The first and second external electrodes 31 and 32 may be formed of a conductive material identical to that of the first and second internal electrodes 21 and 22, but the present inventive concept is not limited thereto and the first and second external electrodes 31 and 32 may be formed of one or more conductive metals selected from the group consisting of copper (Cu), silver (Ag), nickel (Ni), and alloys thereof.

The first and second external electrodes 31 and 32 may be formed by applying a conductive paste prepared by adding glass frit to the conductive metal powder and subsequently sintering the same.

According to an exemplary embodiment of the present disclosure, a metal layer formed of copper (Cu) may be further formed on the first external electrode 31 and the second external electrode 32.

In general, an MLCC is mounted on a printed circuit board (PCB), so a nickel/tin plated layer is formed on external electrodes.

However, the MLCC according to an exemplary embodiment of the present disclosure is an embedded MLCC not mounted on a board, and the first external electrode 31 and the second external electrode 32 thereof are electrically connected to circuits of a board through vias of which a material is copper (Cu).

Thus, according to an exemplary embodiment of the present disclosure, a metal layer formed of copper (Cu) having good electrical connectivity with copper (Cu) as a material of the vias of the board may be further formed on the first external electrode 31 and the second external electrode 32.

Meanwhile, the first external electrode 31 and the second external electrode 32 are also formed of copper (Cu) as a main ingredient. However, since these electrodes include glass, in the event of laser beam machining to form the vias in the board, a component contained in the glass may absorb a laser beam, and thus, a problem in which a process depth of the via may not be able to be adjusted may occur.

Thus, according to an exemplary embodiment of the present disclosure, the foregoing problem may be solved by forming the metal layer formed of copper (Cu) on the first external electrode 31 and the second external electrode 32.

A method for forming the metal layer formed of copper (Cu) is not particularly limited and may be formed through plating, for example.

In another example, the metal layer may be formed by applying a conductive paste including copper (Cu) but without glass frit to the first external electrode 31 and the second external electrode 32, without being particularly limited.

In the case of using the foregoing application method, the metal layer after a sintering process may only include copper (Cu).

Referring to FIG. 3, in the multilayer ceramic electronic component according to an exemplary embodiment of the present disclosure, when a distance from ends of the first and second external electrodes 31 and 32 formed on the first and second side surfaces of the ceramic body 10 to a portion of the first and second external electrodes 31 and 32 corresponding to an edge of the first and second leads 21a, 21b, 22a, and 22b is G, a distance of the first and second external electrodes 31 and 32 formed on the first and second side surfaces of the ceramic body 10 to the end surfaces of the ceramic body 10 is BW, and a distance from the end surfaces of the ceramic body 10 to a portion of the first and second external electrodes 31 and 32 corresponding to an edge of the first and second leads 21a, 21b, 22a, and 22b is M, 30 μm≦G<BW−M may be satisfied.

By adjusting the distance G from the ends of the first and second external electrodes 31 and 32 to the portion of the first and second external electrodes 31 and 32 corresponding to an edge of the first and second leads 21a, 21b, 22a, and 22b to satisfy 30 μm≦G<BW−M, degradation in reliability due to infiltration of a plating solution may be prevented.

When the distance G from the ends of the first and second external electrodes 31 and 32 to the portion of the first and second external electrodes 31 and 32 corresponding to the edge of the first and second leads 21a, 21b, 22a, and 22b is less than 30 μm, reliability may be degraded due to infiltration of a plating solution.

When the distance G from the ends of the first and second external electrodes 31 and 32 to the portion of the first and second external electrodes 31 and 32 corresponding to an edge of the first and second leads 21a, 21b, 22a, and 22b is equal to a value obtained by subtracting the distance M from the ends of the ceramic body 10 to the portion of the first and second external electrodes 31 and 32 corresponding to the edge of the first and second leads 21a, 21b, 22a, and 22b, from the distance BW of the first and second external electrodes 31 and 32 formed on the first and second side surfaces of the ceramic body 10 to the end surfaces of the ceramic body 10, a lead may not be formed and thus it may not be possible to connect the internal electrodes and the external electrodes on the both side surfaces of the ceramic body 10.

In addition to the characteristics according to the foregoing exemplary embodiment of the present disclosure, in a multilayer ceramic electronic component according to another exemplary embodiment of the present disclosure, the distance M from the end surfaces of the ceramic body 10 to the portion of the first and second external electrodes 31 and 32 corresponding to the edge of the first and second leads 21a, 21b, 22a, and 22b may satisfy 50 μm M<BW-G.

By adjusting the distance M from the end surfaces of the ceramic body 10 to the portion of the first and second external electrodes 31 and 32 corresponding to the edge of the first and second leads 21a, 21b, 22a, and 22b to satisfy 50 μm≦M<BW−G, the occurrence of delamination may be prevented, thus implementing a multilayer ceramic electronic component having excellent reliability.

When the distance M from the end surfaces of the ceramic body 10 to the portion of the first and second external electrodes 31 and 32 corresponding to the edge of the first and second leads 21a, 21b, 22a, and 22b is less than 50 μm, delamination may be generated to degrade reliability.

In a case in which the distance M from the end surfaces of the ceramic body 10 to the first and second external electrodes 31 and 32 corresponding to the first and second leads 21a, 21b, 22a, and 22b is identical to the value obtained by subtracting the distance G from the distance BW (BW−G), the leads may not be formed, a problem in which the internal electrodes and the external electrodes may not be connected to each other on the side surfaces of the ceramic body 10 may occur.

Meanwhile, according to an exemplary embodiment of the present disclosure, an average thickness te of the first and second external electrodes 31 and 32 formed on the first and second side surfaces of the ceramic body 10 may be equal to or more than 5 μm.

By adjusting the average thickness te of the first and second external electrodes 31 and 32 formed on the first and second side surfaces of the ceramic body 10 to be equal to or more than 5 μm, a degradation of reliability due to infiltration of a plating solution may be prevented.

When the average thickness te of the first and second external electrodes 31 and 32 formed on the first and second side surfaces of the ceramic body 10 is less than 5 μm, the degradation in reliability may occur due to infiltration of a plating solution.

The average thickness to of the first and second external electrodes 31 and 32 formed on the first and second side surfaces of the ceramic body 10, the distance G from the ends of the first and second external electrodes 31 and 32 to the portion of the first and second external electrodes 31 and 32 corresponding to the edge of the first and second leads 21a, 21b, 22a, and 22b, the distance BW of the first and second external electrodes 31 and 32 formed on the first and second side surfaces of the ceramic body 10 to the end surfaces of the ceramic body 10, and the distance M from the end surfaces of the ceramic body 10 to the portion of the first and second external electrodes 31 and 32 corresponding to the edge of the first and second leads 21a, 21b, 22a, and 22b may be measured by scanning images of the cross-sections of the ceramic body 10 in the length-width direction through a scanning electronic microscope (SEM) as illustrated in FIG. 3.

For example, as illustrated in FIG. 3, in images obtained by scanning length-width (L-W) directional cross-sections of the ceramic body 10 taken from a central portion in the thickness (T) direction of the ceramic body 10 by an SEM, the distances and thicknesses of the first and second external electrodes 31 and 32 may be measured and obtained.

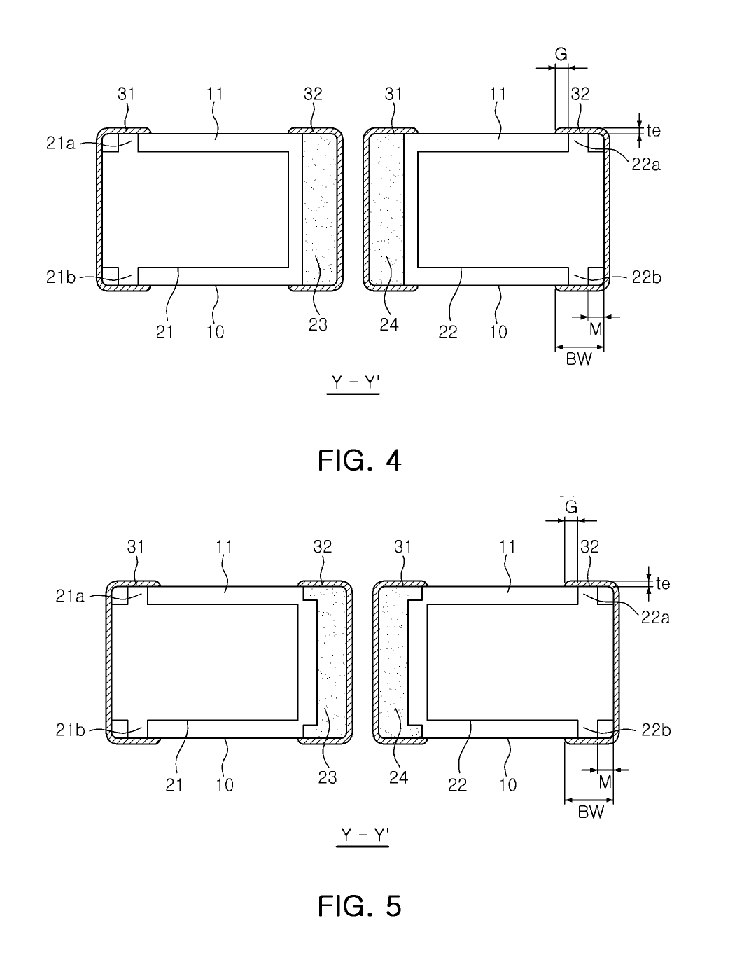

FIG. 4 is a cross-sectional view taken along line Y-Y′ of FIG. 1 according to another exemplary embodiment of the present disclosure.

FIG. 5 is a cross-sectional view taken along line Y-Y′ of FIG. 1 according to another exemplary embodiment of the present disclosure.

Referring to FIGS. 4 and 5, the first and second dummy electrodes 23 and 24 of an embedded MLCC according to an exemplary embodiment of the present disclosure may be formed to have various shapes.

Referring to FIG. 4, the first and second dummy electrodes 23 and 24 may be exposed to the first and second side surfaces, as well as to the end surfaces of the ceramic body 10, unlike the first and second internal electrodes 21 and 22.

Also, as illustrated in FIG. 5, the first and second dummy electrodes 23 and 24 may be exposed to the first and second side surfaces, as well as to the end surfaces of the ceramic body 10, and may have a “E” form in which a distance of the portions exposed to the first and second side surfaces in the length direction of the ceramic body is greater than that of a central portion thereof in the length direction of the ceramic body.

In this case, however, in order to prevent a short defect, the portions of the first and second dummy electrodes 23 and 24 exposed to the first and second side surfaces may only be formed inwardly of the portions in which the first and second external electrodes 31 and 32 are formed.

Through the first and second dummy electrodes 23 and 24 as illustrated in FIGS. 4 and 5, flatness of the external electrodes of the embedded MLCC in the length and width directions may be further enhanced while further increasing the effect of reducing a dimple defect, a problem in which vias are lopsided when a via process for an electrical connection with a board is performed.

In another exemplary embodiment of the present disclosure, an embedded multilayer ceramic electronic component may include a ceramic body 10 including dielectric layers 11 and having first and second main surfaces opposing each other, first and second side surfaces opposing each other, and first and second end surfaces opposing each other; first internal electrodes 21 and second internal electrodes 22 stacked on each other, having the dielectric layers 11 interposed therebetween, and having first and second leads 21a, 21b, 22a, and 22b exposed to the first and second side surfaces, respectively; first dummy electrodes 23 formed to be coplanar with the first internal electrodes 21 and spaced apart from each other by a predetermined distance; and second dummy electrodes 24 formed to be coplanar with the second internal electrodes 22 and spaced apart from each other by a predetermined distance; and first and second external electrodes 31 and 32 formed to extend from the first and second end surfaces to the first and second main surfaces and the first and second side surfaces of the ceramic body 10, respectively, wherein when a distance from ends of the first and second external electrodes 31 and 32 formed on the first and second side surfaces of the ceramic body 10 of the MLCC to a portion of the first and second external electrodes 31 and 32 corresponding to an edge of the first and second leads 21a, 21b, 22a, and 22b is G, a distance of the first and second external electrodes 31 and 32 formed on the first and second side surfaces of the ceramic body 10 to the end surfaces of the ceramic body 10 is BW, and a distance from the end surfaces of the ceramic body 10 to a portion of the first and second external electrodes 31 and 32 corresponding to an edge of the first and second leads 21a, 21b, 22a, and 22b is M, 50 μm≦M<BW−G is satisfied.

Distances of the first and second dummy electrodes 23 and 24 in the length direction of the ceramic body 10 may be equal to or less than 30 μm

The first and second leads 21a, 21b, 22a, and 22b may be formed to be spaced apart from both end surfaces of the ceramic body 10 by a predetermined distance.

An average thickness of the first and second external electrodes formed on the first and second side surfaces of the ceramic body 10 may be equal to or more than 5 μm.

A metal layer formed of copper (Cu) may be formed on the first and second external electrodes 31 and 32.

Other characteristics of the MLCC according to another exemplary embodiment of the present disclosure are the same as those of the MLCC according to the foregoing exemplary embodiment of the present disclosure, so a detailed description thereof will be omitted.

In a method of manufacturing an embedded multilayer ceramic electronic component according to an exemplary embodiment of the present disclosure, first, a slurry including powder such as barium titanate (BaTiO₃) powder, or the like, may be coated on a carrier film and dried to prepare a plurality of ceramic green sheets, thus forming dielectric layers.

The ceramic green sheet may be fabricated as a sheet having a thickness of a few micrometers (μm) by mixing a ceramic powder, a binder, and a solvent to prepare a slurry and treating the slurry with a doctor blade method.

Next, a conductive paste for an internal electrode including 40 to 50 parts by weight of a nickel powder having an average particle size ranging from 0.1 μm to 0.2 μm may be prepared.

A conductive paste for an internal electrode may be coated on the green sheet according to a screen printing method to form an internal electrode, and 200 to 300 layers of the internal electrodes may be stacked to fabricate a ceramic body.

Thereafter, a first external electrode and a second external electrode including a conductive metal and glass may be formed on upper and lower surfaces and end portions of the ceramic body.

The conductive metal may be one or more selected from a group consisting of, for example, copper (Cu), silver (Ag), nickel (Ni), and alloys thereof, but the conductive metal is not particularly limited.

Glass is not particularly limited and a material having a composition the same as that of glass used for fabricating external electrodes of a general MLCC may be used.

The first and second external electrodes may be formed on the upper and lower surfaces and end portions of the ceramic body so as to be electrically connected to the first and second internal electrodes.

Thereafter, a metal layer formed of copper (Cu) may be formed on the first and second external electrodes.

A description of the parts having characteristics the same as those of the embedded multilayer ceramic electronic component according to the foregoing exemplary embodiment of the present disclosure as described above will be omitted.

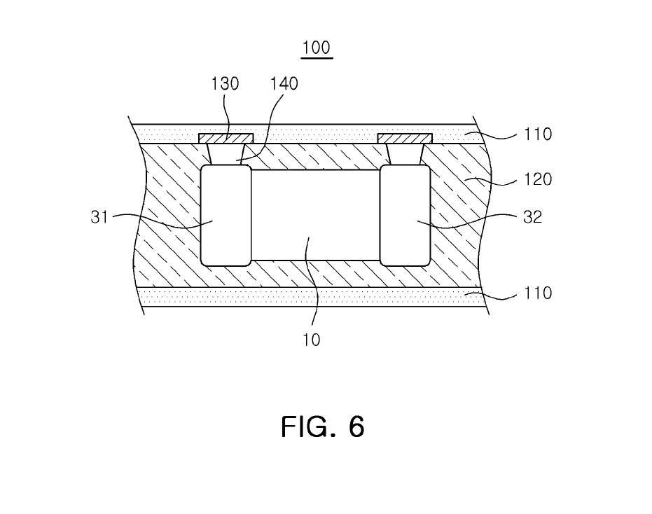

FIG. 6 is a cross-sectional view of a printed circuit board (PCB) 100 having an embedded multilayer ceramic electronic component therein according to an exemplary embodiment of the present disclosure.

Referring to FIG. 6, the PCB 100 including a multilayer ceramic electronic component embedded therein according to an exemplary embodiment of the present disclosure may include an insulating substrate 110; and an embedded multilayer ceramic electronic component according to an exemplary embodiment of the present disclosure.

The insulating substrate 110 may have a structure including an insulating layer 120, and may include a conductive pattern 130 and a conductive via hole 140 constituting various types of interlayer circuits as illustrated in FIG. 6, as necessary. The insulating substrate 110 may be the PCB 100 including a multilayer ceramic electronic component formed therein.

After being inserted into the PCB 100, the multilayer ceramic electronic component may undergo various severe environments during a post-process such as a heat treatment, or the like, performed on the PCB 100.

In particular, contraction and expansion of the PCB 100 during the heat treatment process is directly transferred to the multilayer ceramic electronic component insertedly positioned in the PCB 100 to apply stress to a bonding surface of the multilayer ceramic electronic component and the PCB 100.

When the stress applied to the bonding surface of the multilayer ceramic electronic component and the PCB 100 is higher than adhesive bonding strength, the bonding surface may be separated to cause a delamination defect.

The adhesive bonding strength between the multilayer ceramic electronic component and the PCB 100 is proportional to electrochemical bonding force of the multilayer ceramic electronic component and the PCB 100 and an effective surface area of the bonding surface, and here, in order to enhance an effective surface area of the bonding surface between the multilayer ceramic electronic component and the PCB 100, surface roughness of the multilayer ceramic electronic component may be controlled to improve a delamination phenomenon between the multilayer ceramic electronic component and the PCB 100.

Hereinafter, the present disclosure will be described in further detail through embodiment examples, but the present inventive concept is not limited thereto.

### Embodiment Example

According to an embodiment example, an embedded multilayer ceramic electronic component was fabricated such that an average thickness to of the first and second external electrodes formed on the first and second side surfaces of the ceramic body, a distance G from the ends of the first and second external electrodes to a portion of the first and second external electrodes corresponding to an edge of the first and second leads, and a distance M from the end surfaces of the ceramic body to a portion of the first and second external electrodes corresponding to an edge of the first and second leads satisfied the range of the numeral values according to an exemplary embodiment of the present disclosure.

### Comparative Example

According to a comparative example, an embedded multilayer ceramic electronic component was fabricated under the same conditions as those of the embodiment examples, except that the average thickness te of the first and second external electrodes formed on the first and second side surfaces of the ceramic body, the distance G from the ends of the first and second external electrodes to a portion of the first and second external electrodes corresponding to an edge of the first and second leads, and a distance M from the end surfaces of the ceramic body to a portion of the first and second external electrodes corresponding to an edge of the first and second leads were outside of the range of the numeral values according to an exemplary embodiment of the present disclosure.

Table 1 below shows a comparison of reliability of samples according to values of the average thickness te of the first and second external electrodes formed on the first and second side surfaces of the ceramic body and the distance G from the ends of the first and second external electrodes to the first and second external electrodes corresponding to the first and second leads of the embedded multilayer ceramic electronic component according to an exemplary embodiment of the present disclosure.

The evaluation of reliability was determined based on a degradation of accelerated life due to infiltration of a plating solution. In detail, reliability was evaluated under a humidity condition 8585 (temperature: 85° C., humidity: 85%) for one hour by applying a rated voltage. Samples having a defective rate less than 0.01% is indicated by ⊚, samples having a defective rate ranging from 0.01% to 1.00% is indicated by ∘, samples having a defective rate ranging from 1.00% to 50% is indicated by Δ, and samples having a defective rate exceeding 50% is indicated by X.

TABLE 1

| | Average thickness | | |
|---|---|---|---|
| | (te) of external | | Evaluation of |
| Sample | electrode (μm) | G (μm) | reliability |
| *1 | 1.00 | 10 | X |
| *2 | 1.00 | 20 | X |
| *3 | 1.00 | 30 | X |
| *4 | 1.00 | 40 | X |
| *5 | 1.00 | 50 | X |
| *6 | 3.00 | 10 | Δ |
| *7 | 3.00 | 20 | Δ |
| *8 | 3.00 | 30 | Δ |
| *9 | 3.00 | 40 | Δ |
| *10 | 3.00 | 50 | Δ |
| *11 | 5.00 | 10 | Δ |
| *12 | 5.00 | 20 | Δ |
| 13 | 5.00 | 30 | ◯ |
| 14 | 5.00 | 40 | ⊚ |
| 15 | 5.00 | 50 | ⊚ |
| *16 | 7.00 | 10 | Δ |
| *17 | 7.00 | 20 | Δ |
| 18 | 7.00 | 30 | ◯ |
| 19 | 7.00 | 40 | ⊚ |
| 20 | 7.00 | 50 | ⊚ |

*Comparative example

Referring to Table 1, in case of samples 1 to 12 as comparative examples, the average thickness to of the first and second external electrodes formed on the first and second side surfaces of the ceramic body was outside of the range of the numerical values of the present disclosure, indicating that reliability is problematic due to a degradation of accelerated life due to infiltration of a plating solution.

In case of samples 16 and 17 as comparative examples, the distance G from the ends of the first and second external electrodes to a portion f the first and second external electrodes corresponding to an edge of the first and second leads are outside of the range of the numeral values of the present disclosure, having a problem in terms of reliability.

Meanwhile, in case of samples 13 to 15 and 18 to 20 as embodiment examples, the range of numerical values of the present disclosure is satisfied, providing excellent reliability.

Table 2 below shows a comparison of reliability of samples according to values of the distance M from the end surfaces of the ceramic body to a portion of the first and second external electrodes corresponding to an edge of the first and second leads of the embedded multilayer ceramic electronic component according to an exemplary embodiment of the present disclosure.

The evaluation of reliability was provided by determining whether or not delamination occurred. In detail, delamination was determined through a cutting plane mold inspection on the ceramic body. Samples having a defective rate less than 0.01% is indicated by ⊚, samples having a defective rate ranging from 0.01% to 1.00% is indicated by ∘, samples having a defective rate ranging from 1.00% to 50% is indicated by Δ, and samples having a defective rate exceeding 50% is indicated by X.

TABLE 2

| Sample | M (μm) | Evaluation of reliability |
|---|---|---|
| *21 | 20 | X |
| *22 | 25 | X |
| *23 | 30 | X |
| *24 | 35 | X |
| *25 | 40 | Δ |
| *26 | 45 | Δ |
| 27 | 50 | ◯ |
| 28 | 55 | ◯ |
| 29 | 65 | ◯ |
| 30 | 70 | ⊚ |
| 31 | 75 | ⊚ |
| 32 | 80 | ⊚ |

*Comparative example

Referring to Table 2, in case of samples 21 to 26 as comparative examples, the distance M from the end surfaces of the ceramic body to a portion of the first and second external electrodes corresponding to an edge of the first and second leads is outside of the range of the numerical values of the present disclosure, resulting in indicating that reliability is problematic due to delamination.

Meanwhile, in case of samples 27 to 32 as embodiment examples, the range of numerical values of the present disclosure is satisfied, it can be appreciated that excellent reliability may be exhibited.

Table 3 below shows comparison of dimple defective rates according to whether the first and second internal electrodes use the first and second leads exposed to the side surfaces of the ceramic body and whether dummy electrodes are used in the length direction of the ceramic body in the embedded multilayer ceramic electronic component according to an exemplary embodiment of the present disclosure.

In the evaluation of the dimple defective, samples having a defective rate less than 0.01% is indicated by ⊚, samples having a defective rate ranging from 0.01% to 1.00% is indicated by ∘, samples having a defective rate ranging from 1.00% to 50% is indicated by Δ, and samples having a defective rate exceeding 50% is indicated by X.

TABLE 3

| Use of first and | Use of dummy | Dimple defective |
|---|---|---|
| second leads | electrode | rate |
| ◯ | ◯ | ⊚ |
| ◯ | X | ◯ |
| X | ◯ | ◯ |
| X | X | X |

Referring to Table 3, it can be seen that, in the case in which the first internal electrode and the second internal electrode employ the first and second leads exposed to the side surfaces of the ceramic body, in the case in which dummy electrodes are used in the length direction of the ceramic body, or in the case in which both the first and second leads and the dummy electrodes are used, the dimple defective rates are relatively low, providing relatively excellent reliability.

Meanwhile, it can be seen that, in the cases in which the first and second leads and dummy electrodes are not used, dimple defective rates are high, causing degraded reliability.

As set forth above, according to exemplary embodiments of the present disclosure, since the dummy electrodes are formed to be spaced apart from the internal electrodes and the internal electrodes are extended to be exposed to the side surfaces of the ceramic body in the embedded multilayer ceramic electronic component, the flatness of the external electrodes of the embedded multilayer ceramic electronic component in the length and width directions may be enhanced, and thus, dimple deficiency, a problem in which vias are lopsided in a via process for an electrical connection with a board may be reduced.

Also, since the internal electrodes are extended to be exposed to the side surfaces of the ceramic body in the embedded multilayer ceramic electronic component, a current path may be shortened to reduce ESL.

While exemplary embodiments have been shown and described above, it will be apparent to those skilled in the art that modifications and variations could be made without departing from the spirit and scope of the present disclosure as defined by the appended claims.

What is claimed is:

1. An embedded multilayer ceramic electronic component comprising:
a ceramic body including dielectric layers and having first and second main surfaces opposing each other, first and second side surfaces opposing each other, and first and second end surfaces opposing each other;
first internal electrodes and second internal electrodes stacked on each other, having the dielectric layers interposed therebetween, and having first and second leads exposed to the first and second side surfaces, respectively;
first dummy electrodes formed to be coplanar with the first internal electrodes and spaced apart from each other by a predetermined distance, and second dummy electrodes formed to be coplanar with the second internal electrodes and spaced apart from each other by a predetermined distance; and
first and second external electrodes formed to extend from the first and second end surfaces of the ceramic body to the first and second main surfaces and the first and second side surfaces thereof, respectively,
wherein when a distance from ends of the first and second external electrodes formed on the first and second side surfaces of the ceramic body to a portion of the first and second external electrodes corresponding to an edge of the first and second leads is G, a distance of the first and second external electrodes formed on the first and second side surfaces of the ceramic body to the end surfaces of the ceramic body is BW, and a distance from the end surfaces of the ceramic body to a portion of the first and second external electrodes corresponding to an edge of the first and second leads is M, 30 μm≦G<BW−M is satisfied.

2. The embedded multilayer ceramic electronic component of claim 1, wherein the distance M from the end surfaces of the ceramic body to the portion of the first and second external electrodes corresponding to the edge of the first and second leads satisfies 50 μm≦M<BW−G.

3. The embedded multilayer ceramic electronic component of claim 1, wherein distances of the first and second dummy electrodes in the length direction of the ceramic body are equal to or less than 30 μm.

4. The embedded multilayer ceramic electronic component of claim 1, wherein the first and second leads are spaced apart from both end surfaces of the ceramic body by a predetermined distance.

5. The embedded multilayer ceramic electronic component of claim 1, wherein an average thickness of the first and second external electrodes formed on the first and second side surfaces of the ceramic body is equal to or more than 5 μm.

6. The embedded multilayer ceramic electronic component of claim 1, wherein the first and second external electrodes include a metal layer formed of copper (Cu) formed thereon.

7. The embedded multilayer ceramic electronic component of claim 6, wherein the metal layer is formed through plating.

8. An embedded multilayer ceramic electronic component comprising:
a ceramic body including dielectric layers and having first and second main surfaces opposing each other, first and second side surfaces opposing each other, and first and second end surfaces opposing each other;
first internal electrodes and second internal electrodes stacked on each other, having the dielectric layer interposed therebetween, and having first and second leads exposed to the first and second side surfaces of the ceramic body, respectively;
first dummy electrodes formed to be coplanar with the first internal electrodes and spaced apart from each other by a predetermined distance, and second dummy electrodes formed to be coplanar with the second internal electrodes and spaced apart from each other by a predetermined distance; and
first and second external electrodes formed to extend from the first and second end surfaces of the ceramic body to the first and second main surfaces and the first and second side surfaces thereof, respectively,
wherein when a distance from ends of the first and second external electrodes formed on the first and second side surfaces of the ceramic body to a portion of the first and second external electrodes corresponding to an edge of the first and second leads is G, a distance of the first and second external electrodes formed on the first and second side surfaces of the ceramic body to the end surfaces of the ceramic body is BW, and a distance from the end surfaces of the ceramic body to a portion of the first and second external electrodes corresponding to an edge of the first and second leads is M, 50 μm≦M<BW−G is satisfied.

9. The embedded multilayer ceramic electronic component of claim 8, wherein distances of the first and second dummy electrodes in the length direction of the ceramic body are equal to or less than 30 μm.

10. The embedded multilayer ceramic electronic component of claim 8, wherein the first and second leads are spaced apart from both end surfaces of the ceramic body by a predetermined distance.

11. The embedded multilayer ceramic electronic component of claim 8, wherein an average thickness of the first and second external electrodes formed on the first and second side surfaces of the ceramic body is equal to or more than 5 μm.

12. The embedded multilayer ceramic electronic component of claim 8, wherein the first and second external electrodes include a metal layer formed of copper (Cu) formed thereon.

13. The embedded multilayer ceramic electronic component of claim 12, wherein the metal layer is formed through plating.

14. A printed circuit board (PCB) having an embedded multilayer ceramic electronic component, the PCB comprising:
an insulating substrate; and
the embedded multilayer ceramic electronic component of claim 1 installed in the insulating substrate.

15. A printed circuit board (PCB) having an embedded multilayer ceramic electronic component, the PCB comprising:
an insulating substrate; and
the embedded multilayer ceramic electronic component of claim 8 installed in the insulating substrate.
